(19) United States
(12) Patent Application Publication
(10) Pub. No.: US 2017/0263864 A1
(43) Pub. Date: Sep. 14, 2017

(54) ELECTRONIC DEVICE

(71) Applicant: KABUSHIKI KAISHA TOYOTA CHUO KENKYUSHO, Nagakute-shi, Aichi-ken (JP)

(72) Inventors: Yumi SAITO, Nagakute-shi (JP); Takashi KATSUNO, Nagakute-shi (JP); Tsutomu UESUGI, Nagakute-shi (JP)

(73) Assignee: KABUSHIKI KAISHA TOYOTA CHUO KENKYUSHO, Nagakute-shi, Aichi-ken (JP)

(21) Appl. No.: 15/309,926

(22) PCT Filed: Sep. 17, 2015
(86) PCT No.: PCT/JP2015/076529

§ 371 Date: Nov. 9, 2016

(30) Foreign Application Priority Data
Oct. 17, 2014 (JP) 2014-212695

(51) Int. Cl. H01L 45/00; H01L 41/09

(52) U.S. Cl. CPC H01L 45/147; H01L 45/1226; H01L 45/1253; H01L 41/0973; H01L 45/12

(57) ABSTRACT

An electronic device includes a substrate, a channel portion, a first electrode, a second electrode, and a shape change generation portion. The channel portion is provided above the substrate and includes a phase transition material that undergoes a phase transition between a metal phase and an insulator phase owing to shape change. The first electrode is provided above the channel portion and electrically connected to a part of an upper surface of the channel portion. The second electrode is provided above the channel portion and electrically connected to another part of the upper surface of the channel portion. The shape change generation portion is configured to force the channel portion to cause shape change.

### TECHNICAL FIELD

The art disclosed in herein relates to an electronic device. In particular, the art disclosed herein relates to an electronic device that comprises a channel portion that includes a phase transition material that undergoes a phase transition between a metal phase and an insulator phase.

### BACKGROUND ART

Electronic devices that utilize a phase transition material that undergoes a phase transition between a metal phase and an insulator phase are under development. Japanese Patent Application Publication No. 2011-243632 discloses an electronic device that has a channel portion to which a phase transition material of this type is applied. This electronic device is configured to be able to control the phase transition of the phase transition material in the channel portion, and operates to allow a current to flow in the channel portion when the phase transition material is in a metal phase, and operates to interrupt the current that flows in the channel portion when the phase transition material is in an insulator phase.

### SUMMARY OF INVENTION

### Technical Problem

The electronic device in Japanese Patent Application Publication No. 2011-243632 is configured such that high-concentration electric charges are injected from an ionic liquid into the channel portion, so as to cause a phase transition in the phase transition material in the channel portion. Accordingly, this electronic device requires an encapsulating structure for encapsulating the ionic liquid in a state of being in contact with the channel portion. However, it is technically difficult to construct an encapsulating structure that can stably encapsulate an ionic liquid for a long period of time. The present disclosure has an object of providing the art that improves reliability in the electronic device that comprises the channel portion that includes the phase transition material.

### Solution to Technical Problem

One aspect of an electronic device disclosed herein comprises a substrate, a channel portion, a first electrode, a second electrode, and a shape change generation portion. The channel portion is provided above the substrate and includes a phase transition material that undergoes a phase transition between a metal phase and an insulator phase owing to shape change. The first electrode is provided above the channel portion and electrically connected to a part of an upper surface of the channel portion. The second electrode is provided above the channel portion and electrically connected to another part of the upper surface of the channel portion. The shape change generation portion is configured to force the channel portion to cause shape change.

In the electronic device in the above-described embodiment, the shape change generation portion forces the channel portion to cause shape change, to thereby be able to cause a phase transition in the phase transition material in the channel portion. In the electronic device in the above-described embodiment, a phase transition can be caused in the channel portion without using an ionic liquid. Accordingly, the electronic device in the above-described embodiment can achieve high reliability.

### BRIEF DESCRIPTION OF DRAWINGS

FIG. 1 schematically shows a cross-sectional view of a main part of an electronic device in a first embodiment;

FIG. 2 shows one step of a method of manufacturing the electronic device in the first embodiment;

FIG. 3 shows one step of the method of manufacturing the electronic device in the first embodiment;

FIG. 4 shows one step of the method of manufacturing the electronic device in the first embodiment;

FIG. 5 schematically shows a cross-sectional view of a main part of an electronic device in a second embodiment;

FIG. 6 shows one step of a method of manufacturing the electronic device in the second embodiment;

FIG. 7 shows one step of the method of manufacturing the electronic device in the second embodiment;

FIG. 8 schematically shows a cross-sectional view of a main part of a variation of the electronic device in the second embodiment;

FIG. 9 schematically shows a cross-sectional view of a main part of a variation of the electronic device in the second embodiment;

FIG. 10 schematically shows a cross-sectional of a main part of a variation of the electronic device in the second embodiment;

FIG. 11 schematically shows a cross-sectional view of a main part of an electronic device in a third embodiment;

FIG. 12 shows one step of a method of manufacturing the electronic device in the third embodiment;

FIG. 13 shows one step of the method of manufacturing the electronic device in the third embodiment; and

FIG. 14 shows one step of the method of manufacturing the electronic device in the third embodiment.

### DESCRIPTION OF EMBODIMENTS

### Preferred Aspects of Invention

Preferred aspects of the art disclosed herein will hereinafter be summarized. Notably, each of the items described below has technical utility independently.

One aspect of an electronic device disclosed herein may comprises a substrate, a channel portion, a first electrode, a second electrode, and a shape change generation portion. The substrate may be of any type as long as it supports the channel portion, and its material is not particularly limited. It should be noted, however, that the substrate is desirably constituted of an insulator material so as to restrain leakage of a current that flows in the channel portion. The channel portion is provided above the substrate and includes a phase transition material that undergoes a phase transition between a metal phase and an insulator phase owing to shape change. The channel portion may be provided to be in contact with an upper surface of the substrate, or may be provided above the substrate with another member interposed therebetween. The first electrode is provided above the channel portion and electrically connected to a part of an upper surface of the channel portion. The second electrode is provided above the channel portion and electrically connected to another part of the upper surface of the channel portion. In other words, the first and second electrodes are in contact with different positions of the upper surface of the channel portion, respectively. The shape change generation portion is configured to force the channel portion to cause shape change. The electronic device in the above-described embodiment controls a current that flows in the channel portion by the shape change generation portion, to thereby be able to operate as a transistor that exhibits a switching function. Moreover, the electronic device in the above-described embodiment requires no insulating gate structure, and hence can achieve a high-withstand voltage characteristic.

The phase transition material included in the channel portion may be of any type, as long as it undergoes a phase transition between a metal phase and an insulator phase owing to shape change, and its type is not particularly limited. For example, the phase transition material is desirably a Mott insulator that has a perovskite structure. Such a phase transition material can effectively undergo a phase transition between a metal phase and an insulator phase owing to shape change. Furthermore, the phase transition material is desirably an oxide that contains a d-block transition element (Sc, Ti, V, Cr, Mn, Fe, Co, Ni, Cu, Y, Zr, Nb, Mo, Tc, Ru, Rh, Pd, Ag, Hf, Ta, W, Re, Os, Ir, Pt, Au). Such a phase transition material can more effectively undergo a phase transition between a metal phase and an insulator phase owing to shape change.

The shape change generation portion only needs to be configured to force the channel portion to cause shape change, and its configuration is not particularly limited. The shape change generation portion only needs to be configured to force the channel portion to cause shape change by utilizing various electrical, chemical, or mechanical techniques.

For example, the shape change generation portion may include a piezoelectric element. In this case, the shape change generation portion forces the shape of the channel portion to follow the shape change of the piezoelectric element, to thereby be able to change the shape of the channel portion. A piezoelectric material of the piezoelectric element is not particularly limited. For example, a PZT-based, BaTiO₃-based, BNT-based, Bi layer-based, tungsten bronze-based, or Nb acid-based material can be used as a piezoelectric material of the piezoelectric element. Moreover, the piezoelectric element may be fixed below the substrate. The piezoelectric element may be fixed in contact with a lower surface of the substrate, or may be fixed below the substrate with another member interposed therebetween. The electronic device in the embodiment that includes the piezoelectric element fixed below the substrate can achieve a high-withstand voltage characteristic by adjusting a thickness of the substrate. Alternatively, the piezoelectric element may be fixed above the channel portion. The piezoelectric element may be fixed in contact with the upper surface of the channel portion, or may be fixed above the channel portion with another member interposed therebetween. In the electronic device in the embodiment that includes the piezoelectric element fixed above the channel portion, the piezoelectric element and the channel portion are disposed closely, and hence the channel portion can change its shape by following the shape change of the piezoelectric element at a high speed. Accordingly, the electronic device in this embodiment can achieve high-speed responsivity. Moreover, it is desirable that the electronic device in the embodiment that includes the piezoelectric element fixed above the channel portion should further include an insulating film provided between the channel portion and the piezoelectric element. The electronic device in this embodiment can achieve a high-withstand voltage characteristic by adjusting a thickness of the insulating film.

For example, the shape change generation portion may include an air pressure adjusting member configured to utilize an air pressure difference to force the channel portion to cause shape change. In this case, the air pressure adjusting member may be configured to cause the air pressure difference between an air pressure on an upper surface side of the channel portion and an air pressure on a lower surface side of the substrate. In this case, the electronic device can utilize the channel portion as a diaphragm. The air pressure adjusting member may also be configured to make the air pressure on the lower surface side of the substrate lower than the air pressure on the upper surface side of the channel portion, or may also be configured to make the air pressure on the lower surface side of the substrate higher than the air pressure on the upper surface side of the channel portion. The air pressure adjusting member may also be configured to utilize a negative pressure caused by driving a pump, to force the channel portion to cause shape change, or may also be configured to utilize an attractive force between plates of a capacitor, to force the channel portion to cause shape change.

In the electronic device in the embodiment that includes the piezoelectric element fixed above the channel portion, or in the embodiment that utilizes the channel portion as a diaphragm, a groove is desirably provided in a lower surface of the substrate. When observed from the upper surface of the substrate, the groove is desirably located between the first electrode and the second electrode. According to this embodiment, rigidity of a stacking portion made of the channel portion and the substrate becomes small, and hence the channel portion can deform in response to the shape change of the piezoelectric element or the air pressure difference at a high speed. Accordingly, the electronic devices in these embodiments can achieve high-speed responsivity.

### FIRST EMBODIMENT

The electronic device in each of the embodiments will hereinafter be described with reference to the drawings. Notably, components substantially common to the embodiments have a common sign attached thereto, and repeated description thereof may be omitted.

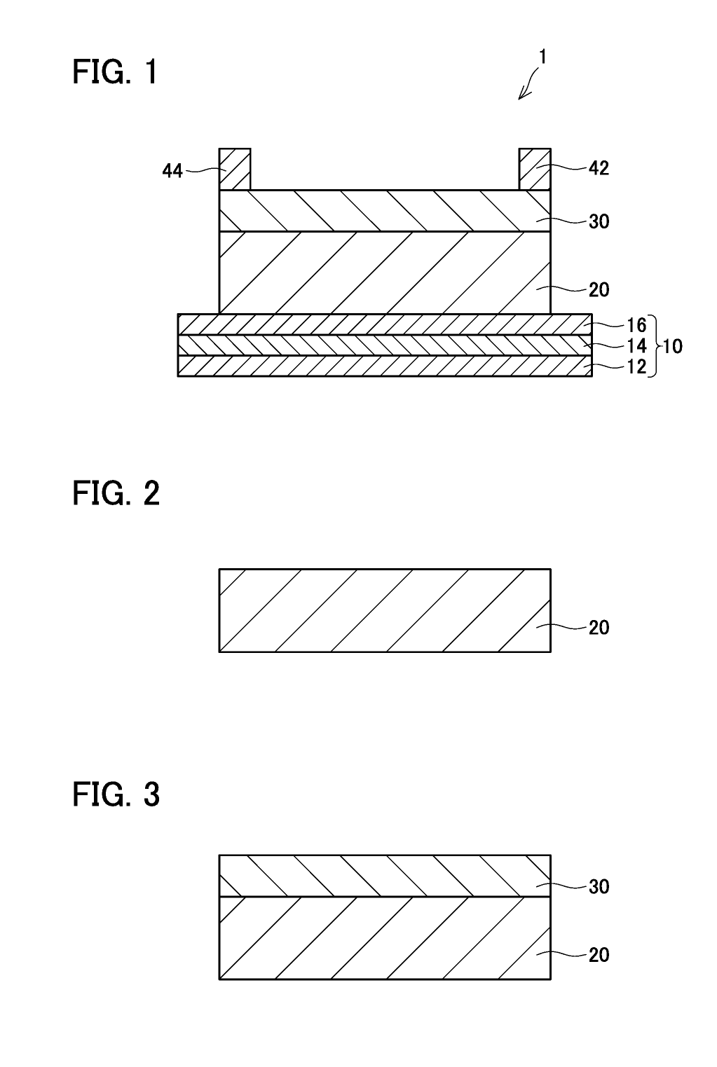

As shown in FIG. 1, an electronic device 1 includes a substrate 20, a channel portion 30, a drain electrode 42, and a source electrode 44.

The substrate 20 is constituted of an insulator material. As mentioned below, the substrate 20 is used as a base when the channel portion 30 is formed by coating. Accordingly, the substrate 20 is desirably constituted of a material that enables the channel portion 30 to be formed thereon by coating, and is desirably constituted of a material that has a lattice constant approximating to a lattice constant of a crystal structure of the channel portion 30. For example, the material of the substrate 20 is desirably a material that has a perovskite structure. In this example, SrTiO₃ (strontium titanate) is used as a material of the substrate 20. The channel portion 30 is provided on the substrate 20, and in contact with an upper surface of the substrate 20. The channel portion 30 is constituted of a phase transition material that undergoes a phase transition between a metal phase and an insulator phase owing to shape change. In this example, a Mott insulator, which is an oxide that has a perovskite structure, is used as a material of the channel portion 30. Specifically, (La,Sr)MnO₃ is used as a material of the channel portion 30. The Mott insulator, which is an oxide that has a perovskite structure, is in an insulator phase when its crystal structure is not distorted, and is in an metal phase when it is compressed in a c-axis direction (i.e., its B-O-B angle is decreased) and its crystal structure is distorted.

The drain electrode 42 is provided above the channel portion 30, and in ohmic contact with a part of an upper surface of the channel portion 30. In this example, titanium or chromium is used as a material of the drain electrode 42. Notably, a surface of the drain electrode 42 may be coated with gold for preventing oxidation.

The source electrode 44 is provided above the channel portion 30, is disposed apart from the drain electrode 42, and is in ohmic contact with a part of the upper surface of the channel portion 30. In this example, titanium or chromium is used as a material of the source electrode 44. Notably, a surface of the source electrode 44 may be coated with gold for preventing oxidation.

The electronic device 1 further includes a piezoelectric element 10. The piezoelectric element 10 is fixed below the substrate 20, and in contact with a lower surface of the substrate 20. The piezoelectric element 10 includes an anode electrode 12, a piezoelectric layer 14, and a cathode electrode 16.

The anode electrode 12 is in contact with one of main surfaces of the piezoelectric layer 14, in other words, a main surface located farther from the substrate 20. The anode electrode 12 is constituted of a conductive material. In this example, Au or Ag is used as a material of the anode electrode 12.

The piezoelectric layer 14 is interposed between the anode electrode 12 and the cathode electrode 16. The piezoelectric layer 14 is constituted of a material that has a piezoelectric effect. In this example, lead zirconate titanate (PZT) is used as a material of the piezoelectric layer 14.

The cathode electrode 16 is in contact with the other of the main surfaces of the piezoelectric layer 14, in other words, a main surface located closer to the substrate 20. The cathode electrode 16 is configured with a conductive material. In this example, Au or Ag is used as a material of the cathode electrode 16.

Next, an operation of the electronic device 1 will be described. The electronic device 1 is used by allowing a high positive voltage (e.g., 600 V) to be applied to the drain electrode 42, and allowing a ground voltage to be applied to the source electrode 44. When a positive voltage is applied to the anode electrode 12 and a ground voltage is applied to the cathode electrode 16 in the piezoelectric element 10, an electric field is generated between the anode electrode 12 and the cathode electrode 16, and the piezoelectric layer 14 deforms to be warped owing to a piezoelectric effect. Since the piezoelectric element 10 and the substrate 20 are firmly fixed, the substrate 20 and the channel portion 30 also deform by following the deformation of the piezoelectric layer 14. As described above, the channel portion 30 has a property of a metal phase when its crystal structure is distorted. Accordingly, when the piezoelectric element 10 deforms, the channel portion 30 is in a state of a metal phase, and a current flows between the drain electrode 42 and the source electrode 44. As such, When a voltage is applied to between the anode electrode 12 and the cathode electrode 16 in the piezoelectric element 10, the electronic device 1 is in an on state.

Next, when a ground voltage is applied to the anode electrode 12 and the cathode electrode 16 in the piezoelectric element 10, no electric field is generated between the anode electrode 12 and the cathode electrode 16, and hence the piezoelectric effect disappears, and the piezoelectric layer 14 returns to an initial state (a non-deformation state). Accordingly, the channel portion 30 also returns to an initial state (a non-deformation state). Therefore, when the piezoelectric element 10 does not deform, the channel portion 30 is in a state of an insulator phase, and no current flows between the drain electrode 42 and the source electrode 44. As such, when no voltage is applied to between the anode electrode 12 and the cathode electrode 16 in the piezoelectric element 10, the electronic device 1 is in an off state.

As described above, in the electronic device 1, the distortion of the channel portion 30 is controlled based on a voltage applied to the piezoelectric element 10, thereby controlling the phase transition between a metal phase and an insulator phase in the channel portion 30. As a result of this, the electronic device 1 can operate as a transistor, on and off of which are switched. based on a voltage applied to the piezoelectric element 10.

Preferred aspects of the electronic device 1 will hereinafter be summarized.

(1) The electronic device 1 is in an off state when no voltage is applied to between the anode electrode 12 and the cathode electrode 16 in the piezoelectric element 10. Accordingly, the electronic device 1 can operate as a normally-off device.

(2) Since the channel portion 30 has a high hardness, it can be switched instantaneously from a deformation state to a non-deformation state. Accordingly, the electronic device 1 can achieve a high-speed turn-off characteristic.

(3) The withstand voltage of the channel portion 30 depends on a thickness of the channel portion 30 and a distance of the channel portion 30 (i.e., a distance between the drain electrode 42 and the source electrode 44). Unlike a channel portion in the conventional semiconductor devices, the withstand voltage of the channel portion 30 does not depend on the impurity concentration. Accordingly, the electronic device 1 can achieve a high-withstand voltage characteristic, and a low on-resistance characteristic.

(4) Moreover, the conventional semiconductor device requires an insulating gate structure that has a gate insulating film having a small film thickness, so as to exert a field effect on the channel portion. Accordingly, in the conventional semiconductor device, there occurs a problem in which, when the semiconductor device is turned off, an electric field concentrates on a drain-side end portion of the gate insulating film in the insulating gate structure, causing an electrical breakdown. On the other hand, the electronic device 1 does not need to exert a field effect on the channel portion 30, and hence does not require such an insulating gate structure. In the electronic device 1, what is only needed is to distort the channel portion 30 so as to control the phase transition of the channel portion 30. Accordingly, in the electronic device 1, even if the substrate 20 interposed between the channel portion 30 and the piezoelectric element 10 has a relatively large thickness, the channel portion 30 can sufficiently be distorted. As such, the electronic device 1 requires no insulating gate structure, and hence can achieve a high-withstand voltage characteristic.

(5) The channel portion 30 undergoes a phase transition between a metal phase and an insulator phase owing to shape change. In other words, the electronic device 1 does not utilize a field effect, and hence is resistant to a voltage noise from an outside. The electronic device 1 can achieve high reliability against an external noise.

Next, a method of manufacturing the electronic device 1 will be described. Initially, as shown in FIG. 2, the substrate 20 is prepared. As the substrate 20, a single-crystal substrate configured of SrTiO₃ (strontium titanate) is used.

Next, as shown in FIG. 3, the channel portion 30 is formed by coating on the upper surface of the substrate 20. A PLD method, a sputtering method, a CVD method, an ALD method, an MBE method, or a spin coating method can be utilized as a coating method.

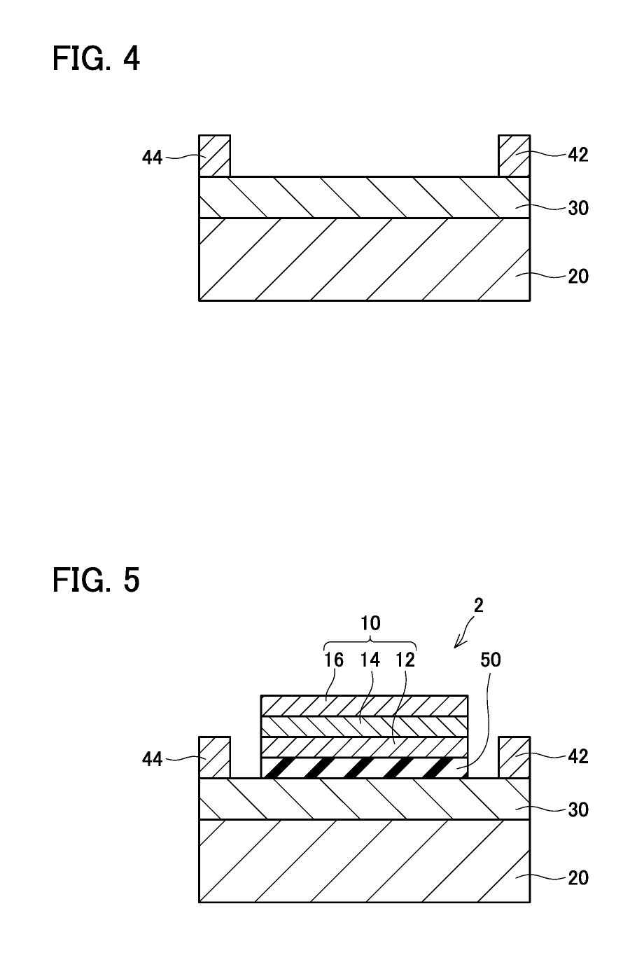

Next, as shown in FIG. 4, the drain electrode 42 and the source electrode 44 are formed on a part of the upper surface of the channel portion 30. As a forming method, the upper surface of the channel portion 30 can be coated with a metal film by an EB vapor deposition method or a sputtering method, and then the metal film can be subjected to patterning by a lift-off method or a dry etching method.

Finally, the piezoelectric element 10, which has been prepared in advance, is joined to the lower surface of the substrate 20 by utilizing a joint method that uses welding or a metal paste. The electronic device 1 is thereby completed.

### SECOND EMBODIMENT

As shown in FIG. 5, an electronic device 2 is characterized in that the piezoelectric element 10 is fixed on the channel portion 30, and additionally, disposed between the drain electrode 42 and the source electrode 44. The electronic device 2 further includes an insulating film 50 interposed between the channel portion 30 and the piezoelectric element 10. The insulating film 50 prevents a current that flows in the channel portion 30 from leaking to the anode electrode 12 in the piezoelectric element 10. Notably, if the channel portion 30 has sufficiently low electrical resistance, the insulating film 50 may not be provided optionally.

If the piezoelectric element 10 is fixed on the upper surface of the channel portion 30, the piezoelectric element 10 and the channel portion 30 are closely disposed. Accordingly, the channel portion 30 can deform by following the deformation of the piezoelectric element 10 at a high speed. Therefore, the electronic device 2 can achieve high-speed responsivity.

Moreover, the electronic device 2 does not need to exert a field effect on the channel portion 30, and hence requires no insulating gate structure. What is only needed in the electronic device 2 is to distort the channel portion 30 so as to control the phase transition of the channel portion 30. Accordingly, in the electronic device 2, even if the insulating film 50 interposed between the channel portion 30 and the piezoelectric element 10 has a relatively large thickness, the channel portion 30 can sufficiently be distorted. As such, the electronic device 2 requires no insulating gate structure, and hence can achieve a high-withstand voltage characteristic.

Next, a method of manufacturing the electronic device 2 will be described. The steps required until the channel portion 30 is formed by coating on the upper surface of the substrate 20 are similar to those in the method of manufacturing the electronic device 1 (see FIGS. 2 and 3).

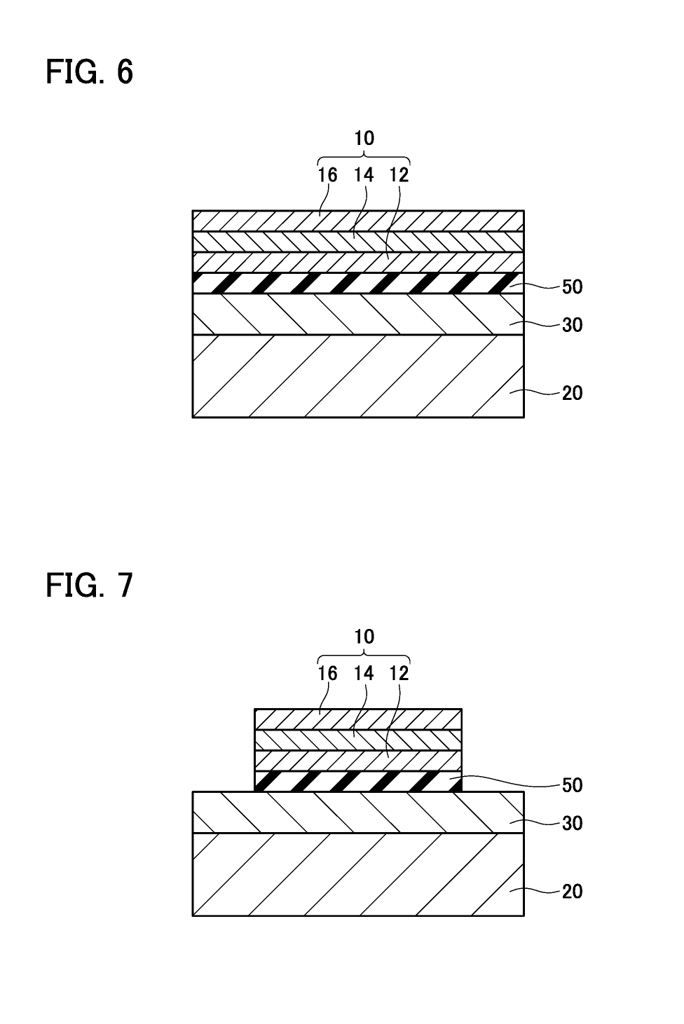

Next, as shown in FIG. 6, the insulating film 50 is formed by coating on the upper surface of the channel portion 30. A CVD method or a PVD method can be utilized as a coating method. Next, the anode electrode 12, the piezoelectric layer 14, and the cathode electrode 16 are successively formed by coating on an upper surface of the insulating film 50. A PLD method, an AD method, or a spin coating method can be utilized as a coating method.

Next, as shown in FIG. 7, a part of a stacked body made of the insulating film 50, the anode electrode 12, the piezoelectric layer 14, and the cathode electrode 16 is removed, to expose a part of the upper surface of the channel portion 30. Finally, the drain electrode 42 and the source electrode 44 are formed on the part of the upper surface of the channel portion 30 thus exposed. As a forming method, the upper suffice of the channel portion 30 can be coated with a metal film by an EB vapor deposition method or a sputtering method, and then the metal film can be subjected to patterning by a lift-off method or a dry etching method. The electronic device 2 is thereby completed.

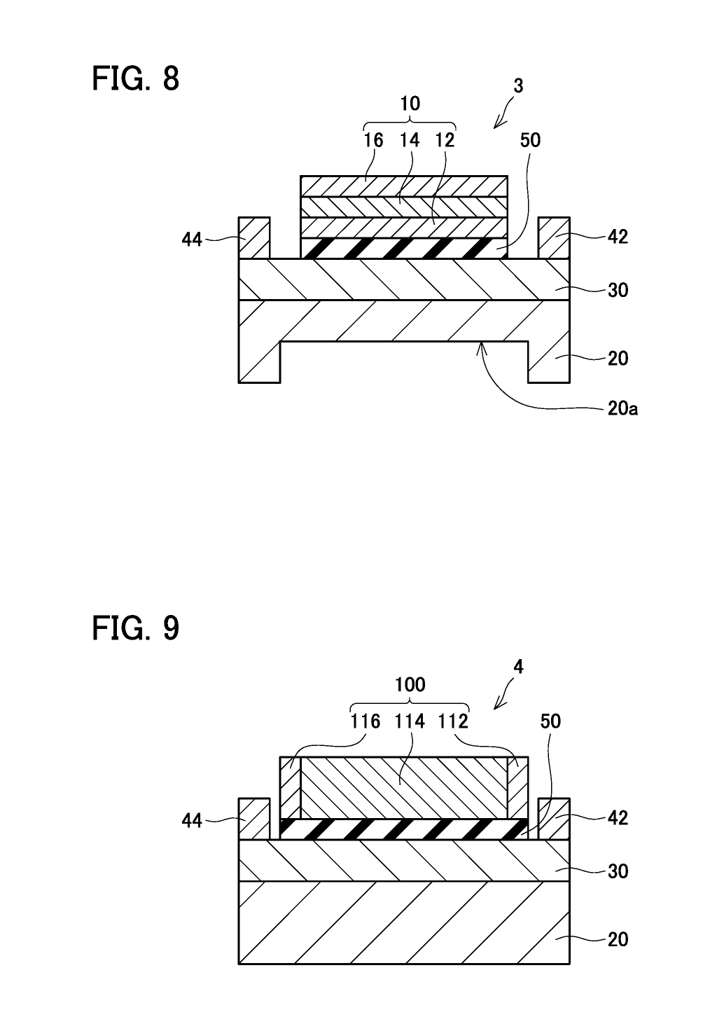

FIG. 8 shows an electronic device 3 in a variation. This example is characterized in that a groove 20a is formed in the lower surface of the substrate 20. When observed from the upper surface of the substrate 20, the groove 20a is located between the drain electrode 42 and the source electrode 44, and disposed to include a range that overlaps the piezoelectric element 10. If such a groove 20a is formed, the rigidity of a stacking portion made of the channel portion 30 and the substrate 20, under the piezoelectric element 10, becomes small between the drain electrode 42 and the source electrode 44. Accordingly, the channel portion 30 can deform by following the deformation of the piezoelectric element 10 at a high speed. The electronic device 3 can achieve high-speed responsivity.

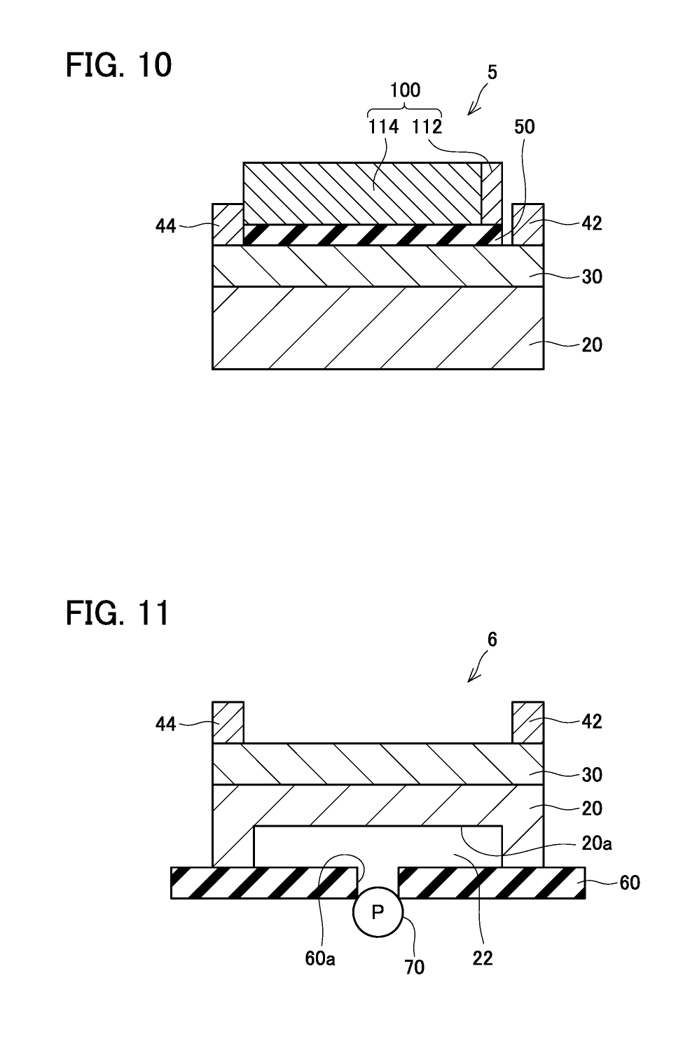

FIG. 9 shows an electronic device 4 in a variation. This example is characterized in that an anode electrode 112 and a cathode electrode 116 in a piezoelectric element 100 are disposed to be arranged laterally with respect to a piezoelectric layer 114. Some materials of the piezoelectric layer 114 may exhibit specificity to a voltage application direction intended for effectively deforming the piezoelectric layer 114. In such a case, the anode electrode 112 and the cathode electrode 116 can be disposed as appropriate in accordance with the material of the piezoelectric layer 114. FIG. 10 shows an electronic device 5 in a variation. This example is a variation of the above-described electronic device 4, and characterized in that one end of the piezoelectric layer 114 is in contact with the source electrode 44. In other words, this example is characterized in that the cathode electrode 116 in the piezoelectric element 100 is removed, and the source electrode 44 plays a role of the cathode electrode 116 as well. The structure of the electronic device 5 is thereby simplified. In this electronic device 5 as well, the piezoelectric layer 114 deforms and the channel portion 30 is brought into a metal phase when a positive voltage is applied to the anode electrode 112, whereas the piezoelectric layer 114 returns to the initial state (the non-deformation state) and the channel portion 30 is brought into an insulator phase when a ground voltage is applied to the anode electrode 112. The electronic device 5 can also operate as a transistor, on and off of which are switched based on a voltage applied to the piezoelectric element 100.

### THIRD EMBODIMENT

As shown in FIG. 11, an electronic device 6 is characterized in that it includes: an insulating layer 60 provided on the lower surface of the substrate 20 and having a through hole 60a provided therein; and a pump 70 that communicates with the through hole 60a in the insulating layer 60. In the electronic device 6, the groove 20a are provided in the lower surface of the substrate 20. The substrate 20 and the insulating layer 60 delimit a negative pressure chamber 22. The pump 70 is configured to communicate with the negative pressure chamber 22 via the through hole 60a in the insulating layer 60. In the electronic device 6, the upper surface of the channel portion 30 is exposed to an atmospheric pressure.

Next, an operation of the electronic device 6 will be described. When the pump 70 stops, the air pressure in the negative pressure chamber 22 is maintained at approximately the same level as that of the air pressure on an upper surface side of the channel portion 30 (the atmospheric pressure). Accordingly, no pressure difference is generated between the air pressure on the upper surface side of the channel portion 30 and the air pressure on a lower surface side of the substrate 20, and hence the channel portion 30 does not deform. At this time, the channel portion 30 is in a state of an insulator phase, and no current flows between the drain electrode 42 and the source electrode 44. As such, when the pump 70 stops, the electronic device 6 is in an off state.

Next, when the pump 70 is driven, the air pressure in the negative pressure chamber 22 is reduced, and a pressure difference is generated between the air pressure on the upper surface side of the channel portion 30 (the atmospheric pressure) and the air pressure on the lower surface side of the substrate 20, causing the channel portion 30 to deform to be warped. Accordingly, the channel portion 30 is brought into a state of a metal phase, and a current flows between the drain electrode 42 and the source electrode 44. As such, when the pump 70 is driven, the electronic device 5 is in an on state.

As described above, in the electronic device 6, the distortion of the channel portion 30 is controlled based on the driving of the pump 70, and the phase transition between a metal phase and an insulator phase is thereby controlled in the channel portion 30. As a result of this, the electronic device 6 can operate as a transistor, on and off of which are switched based on the driving of the pump 70.

Moreover, the electronic device 6 does not need to exert a field effect on the channel portion 30, and hence requires no insulating gate structure. As such, the electronic device 6 requires no insulating gate structure, and hence can achieve a high-withstand voltage characteristic.

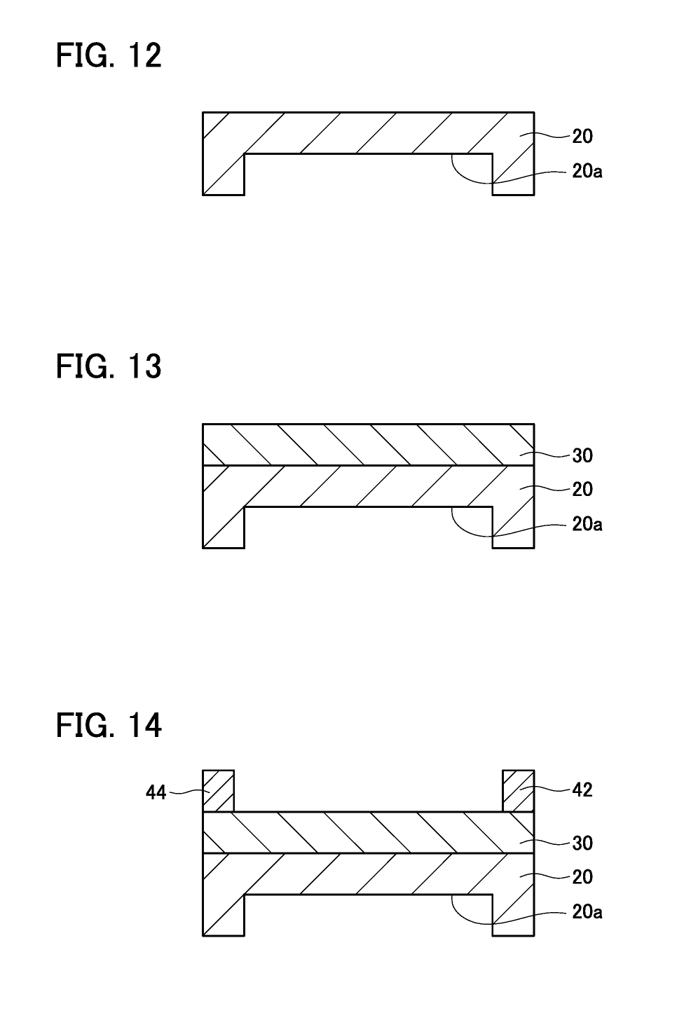

Next, a method of manufacturing the electronic device 6 will be described. Initially, as shown in FIG. 12, the substrate 20 that has the groove 20a provided in the lower surface is prepared. The groove 20a in the substrate 20 can be formed by utilizing an etching technology.

Next, as shown in FIG. 13, the channel portion 30 is formed by coating on the upper surface of the substrate 20. A PLD method, a sputtering method, a CVD method, an ALD method, an MBE method, or a spin coating method can be utilized as a coating method.

Next, as shown in FIG. 14, the drain electrode 42 and the source electrode 44 are formed on a part of the upper surface of the channel portion 30. As a forming method, the upper surface of the channel portion 30 can be coated with a metal film by an EB vapor deposition method or a sputtering method, and then the metal film can be subjected to patterning by a lift-off method or a dry etching method.

Next, the insulating layer 60, which has been prepared in advance, is joined to the lower surface of the substrate 20. Finally, the pump 70 is attached to communicate with the through hole 60a in the insulating layer 60. The electronic device 6 is thereby completed.

Specific examples of the present invention have been described above in details, however, these are merely illustrative, and thus are not intended to limit the scope of the claims. The art described in the appended claims embraces various modifications and variations of the specific examples illustrated above. Moreover, technical elements described in the present specification or the drawings exhibit technical utility alone or in various types of combinations, and are not limited to the combinations described in the originally-filed claims. Moreover, the art illustrated in the present specification or the drawings can concurrently achieve a plurality of objects, and technical utility thereof simply resides in achieving any one of the objects.

1. An electronic device comprising:
a substrate;
a channel portion provided above the substrate and including a phase transition material that undergoes a phase transition between a metal phase and an insulator phase owing to shape change;
a first electrode provided above the channel portion and electrically connected to a part of an upper surface of the channel portion;
a second electrode provided above the channel portion and electrically connected to another part of the upper surface of the channel portion; and
a shape change generation portion configured to force the channel portion to cause shape change.

2. The electronic device according to claim 1, wherein
the shape change generation portion includes a piezoelectric element, and
the piezoelectric element is fixed below the substrate.

3. The electronic device according to claim 1, wherein
the shape change generation portion includes a piezoelectric element, and
the piezoelectric element is fixed above the channel portion.

4. The electronic device according to claim 3, further comprising an insulating film provided between the channel portion and the piezoelectric element

5. The electronic device according to claim 1, wherein
the shape change generation portion includes an air pressure adjusting member configured to utilize an air pressure difference to force the channel portion to cause shape change, and
the air pressure adjusting member is configured to cause the air pressure difference between an air pressure on an upper surface side of the channel portion and an air pressure on a lower surface side of the substrate.

6. The electronic device according to claim 3, wherein
a groove is provided in a lower surface of the substrate, and
when observed from a direction orthogonal to an upper surface of the substrate, the groove is located between the first electrode and the second electrode.

7. The electronic device according to claim 1, wherein
the phase transition material includes a perovskite structure.

8. The electronic device according to claim 7, wherein
the phase transition material is an oxide that contains a d-block transition element.
